(19) United States
(12) Patent Application Publication
(10) Pub. No.: US 2025/0017052 A1
(43) Pub. Date: Jan. 9, 2025

(54) DISPLAY DEVICE AND METHOD OF MANUFACTURING DISPLAY DEVICE

(71) Applicant: Japan Display Inc., Tokyo (JP)

(72) Inventors: Hiroshi TABATAKE, Tokyo (JP); Hiroyuki KIMURA, Tokyo (JP)

(73) Assignee: Japan Display Inc., Tokyo (JP)

(21) Appl. No.: 18/752,802

(22) Filed: Jun. 25, 2024

(30) Foreign Application Priority Data
Jul. 6, 2023 (JP) 2023-111655

(51) Int. Cl. H10K 59/122; H10K 59/12; H10K 59/35; H10K 59/65; H10K 59/80; H10K 71/60

(52) U.S. Cl. CPC H10K 59/122; H10K 59/1201; H10K 59/352; H10K 59/353; H10K 59/65; H10K 59/80517; H10K 71/60

(57) ABSTRACT

According to one embodiment, a display device includes a base, a lower electrode, a rib including an aperture, a partition, an organic layer in contact with the lower electrode through the aperture, and an upper electrode. The lower electrode includes first lower electrodes in a first area on and second lower electrodes in a second area. The aperture includes first apertures overlapping with the first lower electrodes and second apertures overlapping with the second lower electrodes. The partition includes a first partition dividing the first apertures and second partitions dividing each of the second apertures. The second aperture is smaller than the first aperture. Each of the second partitions is connected to other second partition via a transparent conductive layer.

### CROSS-REFERENCE TO RELATED APPLICATION

This application is based upon and claims the benefit of priority from Japanese Patent Application No. 2023-111655, filed Jul. 6, 2023, the entire contents of which are incorporated herein by reference.

### FIELD

Embodiments described herein relate generally to a display device and a method of manufacturing display device.

### BACKGROUND

Recently, display devices with organic light-emitting diodes (OLEDs) applied thereto as display elements have been put into practical use. It is known that electronic apparatus such as smartphone includes the display device.

The electronic apparatus adopts a configuration in which a camera is arranged on a back side of the organic EL display device (display area). This configuration can extend the display area to an area overlapping with the camera.

In this configuration, light may be made incident on a camera (imaging device thereof) through the display device. Therefore, it is necessary to maintain sufficient light transmittance in the display device (in an area of the display area that overlaps with the camera).

### BRIEF DESCRIPTION OF THE DRAWINGS

FIG. 1 is a diagram showing a configuration example of a display device of an embodiment.

FIG. 2 is a diagram showing an example of layout of sub-pixels.

FIG. 3 is a schematic cross-sectional view showing the display device along line A-A in FIG. 2.

FIG. 4 is a schematic cross-sectional view of a partition.

FIG. 5 is a schematic cross-sectional view illustrating a display element formed by using a partition.

FIG. 6 is a schematic cross-sectional view illustrating the display element formed by using the partition.

FIG. 7 is a schematic cross-sectional view illustrating the display element formed by using the partition.

FIG. 8 is a plan view showing parts of an electronic apparatus in which the display device is incorporated.

FIG. 9 is a view schematically showing an example of an arrangement of an aperture included in a rib formed in a first display area.

FIG. 10 is a view schematically showing an example of an aperture included in a rib formed in a second display area.

FIG. 11 is a schematic cross-sectional view showing the display device along line B-B in FIG. 10.

FIG. 12 shows an example of a process of forming the rib, the partition, and a transparent conductive layer in the second display area.

FIG. 13 shows an example of the process of forming the rib, the partition, and the transparent conductive layer in the second display area.

FIG. 14 shows an example of the process of forming the rib, the partition, and the transparent conductive layer in the second display area.

FIG. 15 is a view schematically showing another example of the aperture included in the rib formed in the second display area.

FIG. 16 is a view schematically showing still another example of the aperture included in the rib formed in the second display area.

FIG. 17 is a view schematically showing still another example of the aperture included in the rib formed in the second display area.

### DETAILED DESCRIPTION

In general, according to one embodiment, a display device includes a base, a lower electrode arranged on the base, a rib including an aperture overlapping with the lower electrode, a partition including a lower portion arranged on the rib and an upper portion protruding from side surfaces of the lower portion, an organic layer in contact with the lower electrode through the aperture, and an upper electrode arranged on the organic layer. The lower electrode includes a plurality of first lower electrodes arranged in a first area on the base and a plurality of second lower electrodes arranged in a second area different from the first area. The aperture includes a plurality of first apertures overlapping with the plurality of first lower electrodes and a plurality of second apertures overlapping with the plurality of second lower electrodes. The partition includes a first partition dividing the plurality of first apertures and a plurality of second partitions dividing each of the plurality of second apertures. An area of each of the plurality of second apertures is smaller than an area of each of the plurality of first apertures. Each of the plurality of second partitions is arranged to have gaps between the second partition and other second partition and is connected to the other second partitions via a transparent conductive layer arranged on the rib.

An embodiment will be described with reference to the accompanying drawings.

The disclosure is merely an example, and proper changes within the spirit of the invention, which are easily conceivable by a person of ordinary skill in the art, are included in the scope of the invention as a matter of course. In addition, in some cases, in order to make the description clearer, the widths, thicknesses, shapes and the like, of the respective parts are illustrated schematically in the drawings, rather than as an accurate representation of what is implemented. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

In the figures, an X-axis, a Y-axis and a Z-axis orthogonal to each other are described to facilitate understanding as needed. A direction along the X-axis is referred to as a first direction X, a direction along the Y-axis is referred to as a second direction Y, and a direction along the Z-axis is referred to as a third direction Z. A plan view is defined as appearance when various types of elements are viewed parallel to the third direction Z.

The display device of the present embodiment is an organic electroluminescent display device including an organic light emitting diode (OLED) as a display element, and can be mounted on electronic apparatus such as smartphones. The display device of the present embodiment may be mounted on electronic apparatus other than smartphones (for example, tablets).

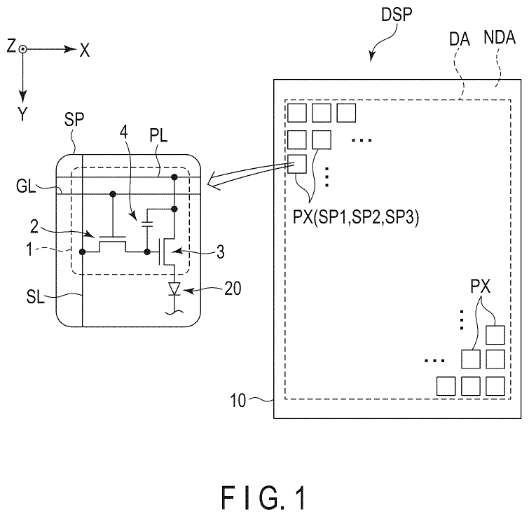

FIG. 1 is an illustration showing a configuration example of a display device DSP according to the present embodiment. The display device DSP has a display area DA where images are displayed and a non-display area NDA around the display area DA, on an insulating base 10. The base 10 may be glass or a flexible resin film.

In this embodiment, the base 10 in planar view has a rectangular shape. However, the shape of the base 10 in plan view is not limited to a rectangular shape, but may also be other shape such as a square, a circle or an ellipse.

The display area DA includes a plurality of pixels PX arrayed (arranged) in a matrix in the first direction X and the second direction Y. Each pixel PX includes a plurality of sub-pixels SP. As an example, the pixel PX includes a red sub-pixel SP1, a green sub-pixel SP2, and a blue sub-pixel SP3. The pixel PX may include a sub-pixel SP of the other color such as white, together with the sub-pixels SP1, SP2, and SP3. In addition, the pixel PX may include a sub-pixel SP of other colors, instead of any of the sub-pixels SP1, SP2, and SP3.

The sub-pixel SP includes a pixel circuit 1 and a display element 20 driven by the pixel circuit 1. The pixel circuit 1 includes a pixel switch 2, a drive transistor 3, and a capacitor 4. The pixel switch 2 and the drive transistor 3 are, for example, switching elements constituted by thin-film transistors.

A gate electrode of the pixel switch 2 is connected to a scanning line GL. Either a source electrode or a drain electrode of the pixel switch 2 is connected to a signal line SL, and the other is connected to a gate electrode of the drive transistor 3 and the capacitor 4. In the drive transistor 3, either the source electrode or the drain electrode is connected to a power line PL and the capacitor 4, and the other is connected to the display element 20.

The configuration of the pixel circuit 1 is not limited to the example shown in FIG. 1. For example, the pixel circuit 1 may include more thin-film transistors and more capacitors.

The display element 20 is an organic light-emitting diode (OLED) serving as a light emitting element. For example, the sub-pixel SP1 includes a display element 20 that emits light of a red wavelength range, the sub-pixel SP2 includes a display element 20 that emits light of a green wavelength range, and the sub-pixel SP3 includes a display element 20 that emits light of a blue wavelength range.

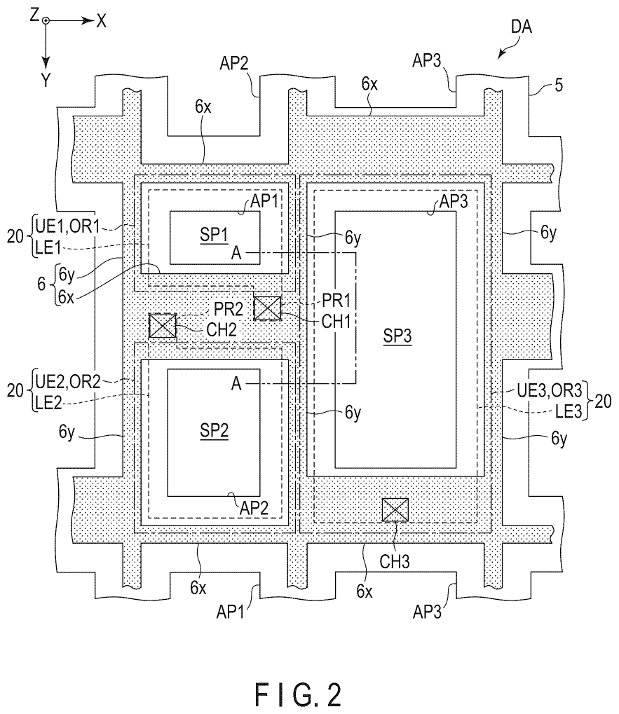

FIG. 2 shows an example of the layout of the sub-pixels SP1, SP2, and SP3. In the example shown in FIG. 2, the sub-pixels SP1 and SP2 are aligned in the direction Y. Furthermore, each of the sub-pixels SP1 and SP2 is arranged with the sub-pixel SP3 in the direction X.

When the sub-pixels SP1, SP2, and SP3 are arranged in the layout shown in FIG. 2, a row in which the sub-pixels SP1 and SP2 are alternately arranged in the direction Y and a row in which the plurality of sub-pixels SP3 are repeatedly arranged in the direction Y are formed in the display area DA. These rows are alternately arranged in the first direction X.

The layout of the sub-pixels SP1, SP2, and SP3 is not limited to the example shown in FIG. 2. As another example, the sub-pixels SP1, SP2, and SP3 in each pixel PX are arranged in order in the first direction X.

A rib 5 and a partition 6 are arranged in the display area DA. The rib 5 includes apertures AP1, AP2, and AP3 in the sub-pixels SP1, SP2, and SP3, respectively. In the example shown in FIG. 2, the area of the aperture AP1 is larger than the area of the aperture AP2, and the area of the aperture AP3 is larger than the area of the aperture AP2. The partition 6 is provided in the boundary between adjacent sub-pixels SP and overlaps with the rib 5 as seen in plan view.

The partition 6 includes a partition 6x extending in the first direction X and a partition 6y extending in the second direction Y. The partition 6x is provided between the apertures AP1 and AP2 which are adjacent to each other in the second direction Y and between two apertures AP3 which are adjacent to each other in the second direction Y. The partition 6y is provided between the apertures AP1 and AP3 which are adjacent to each other in the first direction X and between the apertures AP2 and AP3 which are adjacent to each other in the first direction X.

In the example shown in FIG. 2, the first partition 6x and the second partition 6y are connected to each other. Thus, the partition 6 has a grating pattern surrounding the apertures AP1, AP2, and AP3 as a whole. The partition 6 includes apertures at the sub-pixels SP1, SP2, and SP3, similarly to the rib 5.

In other words, in the present embodiment, the rib 5 and the partition 6 are arranged to divide the sub-pixels SP1, SP2, and SP3 (apertures AP1, AP2, and AP3).

The sub-pixel SP1 includes a lower electrode LE1, an upper electrode UE1, and an organic layer OR1 each overlapping with the aperture AP1. The sub-pixel SP2 includes a lower electrode LE2, an upper electrode UE2, and an organic layer OR2 each overlapping with the aperture AP2. The sub-pixel SP3 includes a lower electrode LE3, an upper electrode UE3, and an organic layer OR3 each overlapping with the aperture AP3. In the example shown in FIG. 2, outer shapes of the upper electrode UE1 and the organic layer OR1 correspond to each other, outer shapes of the upper electrode UE2 and the organic layer OR2 correspond to each other, and outer shapes of the upper electrode UE3 and the organic layer OR3 correspond to each other.

The lower electrode LE1, the upper electrode UE1, and the organic layer OR1 constitute the display element 20 of the sub-pixel SP1. The lower electrode LE2, the upper electrode UE2, and the organic layer OR2 constitute the display element 20 of the sub-pixel SP2. The lower electrode LE3, the upper electrode UE3, and the organic layer OR3 constitute the display element 20 of the sub-pixel SP3.

The lower electrode LE1 is connected to the pixel circuit 1 which drives the sub-pixel SP1 (display element 20 thereof) through a contact hole CH1. The lower electrode LE2 is connected to the pixel circuit 1 which drives the sub-pixel SP2 (display element 20 thereof) through a contact hole CH2. The lower electrode LE3 is connected to the pixel circuit 1 which drives the sub-pixel SP3 (display element 20 thereof) through a contact hole CH3.

In the example shown in FIG. 2, the contact holes CH1 and CH2 entirely overlap with the partition 6x between the apertures AP1 and AP2 adjacent to each other in the direction Y. The contact hole CH3 entirely overlaps with the partition 6x between two apertures AP3 which are adjacent to each other in the second direction Y. As another example, at least parts of the contact holes CH1, CH2, and CH3 may not overlap with the first partition 6x.

In the example shown in FIG. 2, the lower electrodes LE1 and LE2 include protrusions PR1 and PR2, respectively. The protrusion PR1 protrudes from the body of the lower electrode LE1 (portion overlapping with the aperture AP1) toward the contact hole CH1. The protrusion PR2 protrudes from the body of the lower electrode LE2 (portion overlapping with the aperture AP2) toward the contact hole CH2. The contact holes CH1 and CH2 overlap with the protrusions PR1 and PR2, respectively.

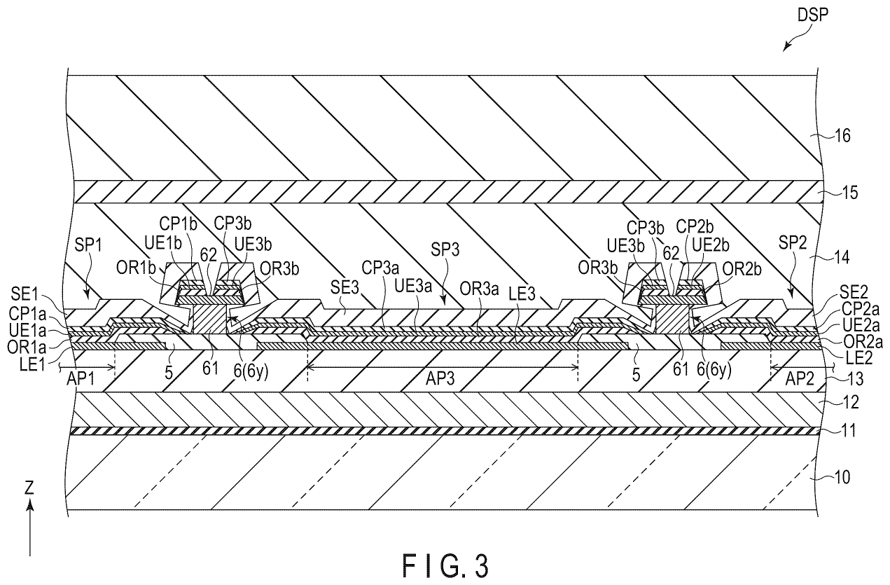

FIG. 3 is a schematic cross-sectional view showing the display device DSP along line A-A in FIG. 2. In the display device DSP, an insulating layer 11 referred to as an undercoat layer is arranged on the base 10 having the transmissive similar to glass material (i.e., on the surface of the side where the display element 20 and the like are arranged).

The insulating layer 11 has, for example, a three-layer stacked structure with a silicon oxide film (SiO), a silicon nitride film (SiN), and a silicon oxide film (SiO). The insulating layer 11 is not limited to the three-layer stacked structure. The insulating layer 11 may have a stacked structure with more than three layers, or may have a single-layer structure or a two-layer stacked structure.

A circuit layer 12 is arranged on the insulating layer 11. The circuit layer 12 includes various circuits and wires that drive the sub-pixels SP (SP1, SP2, and SP3) of the pixel circuit 1, the scanning line GL, the signal line SL, the power line PL, and the like shown in FIG. 1. The circuit layer 12 is covered with an insulating layer 13.

The insulating layer 13 functions as a fattening film which flattens the uneven parts formed by the circuit layer 12. Although not shown in FIG. 3, the above-described contact holes CH1, CH2, and CH3 are provided on the insulating layer 13.

The lower electrodes LE (LE1, LE2, and LE3) are arranged on the insulating layer 13. The rib 5 is arranged on the insulating layer 13 and the lower electrodes LE. Ends (parts) of the lower electrodes LE are covered with the rib 5.

The partition 6 includes a lower portion 61 arranged on the rib 5 and an upper portion 62 that covers an upper surface of the lower portion 61. The upper portion 62 has a greater width in the direction X and the direction Y than the lower portion 61 does. As a result, the partition 6 has a shape in which both ends of the upper portion 62 protrude beyond side surfaces of the lower portion 61. This shape of the partition 6 may be called an overhang shape.

The organic layers OR (OR1, OR2, and OR3) and the upper electrodes (UE1, UE2, and UE3) constitute the display 20 together with the lower electrodes LE (LE1, LE2, and LE3). As shown in FIG. 3, the organic layer OR1 includes a first organic layer OR1a and a second organic layer OR1b spaced apart from each other. The upper electrode UE1 includes a first upper electrode UE1a and a second upper electrode UE1b spaced apart from each other. The first organic layer OR1a is in contact with the lower electrode LE1 through the aperture AP1 and covers a part of the rib 5. The second organic layer OR1b is located above the upper portion 62. The first upper electrode UE1a is opposed to the lower electrode LE1 and covers the first organic layer OR1a. In addition, the first upper electrode UE1a is in contact with the side surfaces of the lower portion 61. The second upper electrode UE1b is located above the partition 6 and covers the second organic layer OR1b.

As shown in FIG. 3, the second organic layer OR2 includes a first organic layer OR2a and a second organic layer OR2b spaced apart from each other. The upper electrode UE2 includes a first upper electrode UE2a and a second upper electrode UE2b spaced apart from each other. The first organic layer OR2a is in contact with the lower electrode LE2 through the aperture AP2 and covers a part of the rib 5. The second organic layer OR2b is located above the upper portion 62. The first upper electrode UE2a is opposed to the lower electrode LE2 and covers the first organic layer OR2a. In addition, the first upper electrode UE2a is in contact with the side surfaces of the lower portion 61. The second upper electrode UE2b is located above the partition 6 and covers the second organic layer OR2b.

As shown in FIG. 3, the organic layer OR3 includes a first organic layer OR3a and a second organic layer OR3b spaced apart from each other. The upper electrode UE3 includes a first upper electrode UE3a and a second upper electrode UE3b spaced apart from each other. The first organic layer OR3a is in contact with the lower electrode LE3 through the aperture AP3 and covers a part of the rib 5. The second organic layer OR3b is located above the upper portion 62. The first upper electrode UE3a is opposed to the lower electrode LE3 and covers the first organic layer OR3a. In addition, the first upper electrode UE3a is in contact with the side surfaces of the lower portion 61. The second upper electrode UE3b is located above the partition 6 and covers the third organic layer OR3b.

In the example shown in FIG. 3, the sub-pixels SP1, SP2, and SP3 include cap layers (optical path adjustment layer) CP1, CP2, and CP3 for adjusting optical property of light emitted from the organic layers OR1, OR2, and OR3, respectively.

The cap layer CP1 includes a first cap layer CPla and a second cap layer CP1b spaced apart from each other. The first cap layer CPla is located in the aperture AP1 and is arranged on the first upper electrode UE1a. The second cap layer CP1b is located above the partition 6 and is arranged on the second upper electrode UE1b.

The cap layer CP2 includes a first cap layer CP2a and a second cap layer CP2b spaced apart from each other. The first cap layer CP2a is located in the aperture AP2 and is arranged on the first upper electrode UE2a. The second cap layer CP2b is located above the partition 6 and is arranged on the second upper electrode UE2b.

The cap layer CP3 includes a first cap layer CP3a and a second cap layer CP3b spaced apart from each other. The first cap layer CP3a is located in the aperture AP3 and is arranged on the first upper electrode UE3a. The second cap layer CP3b is located above the partition 6 and is arranged on the second upper electrode UE3b.

Sealing layers SE1, SE2 and SE3 are provided in the sub-pixels SP1, SP2 and SP3, respectively. The sealing layer SE1 continuously covers each portion of the sub-pixel SP1 such as the first cap layer CPla, the partition 6, and the second cap layer CP1b. The sealing layer SE2 continuously covers each portion of the sub-pixel SP2 such as the first cap layer CP2a, the partition 6, and the second cap layer CP2b. The sealing layer SE3 continuously covers each portion of the sub-pixel SP3 such as the first cap layer CP3a, the partition 6, and the second cap layer CP3b.

In the example shown in FIG. 3, the second organic layer OR1b, the second upper electrode UE1b, the second cap layer CP1b, and the sealing layer SE1 on the partition 6 between the sub-pixel SP1 and the sub-pixel SP3 are spaced apart from the second organic layer OR3b, the second upper electrode UE3b, the second cap layer CP3b, and the sealing layer SE3 on the partition 6. In addition, the second organic layer OR2b, the second upper electrode UE2b, the second cap layer CP2b, and the sealing layer SE2 on the partition 6 between the sub-pixel SP2 and the sub-pixel SP3 are spaced apart from the second organic layer OR3b, the second upper electrode UE3b, the second cap layer CP3b, and the sealing layer SE3 on the partition 6.

The sealing layers SE1, SE2, and SE3 are covered with a resin layer 14 (planarization film). The resin layer 14 is covered with a sealing layer 15. Furthermore, the sealing layer 15 is covered with a resin layer 16.

The insulating layer 13 and the resin layers 14 and 16 are formed of organic materials. The rib 5, and the sealing layers 15 and SE (SE1, SE2 and SE3) are formed of, for example, an inorganic material such as silicon nitride (SiNx).

The lower portion 61 included in the partition 6 is conductive. The upper portion 62 included in the partition 6 may also be conductive. The lower electrode LE may be formed of a transparent conductive oxide such as indium tin oxide (ITO) or may have a stacked structure of a metal material such as silver (Ag) and a conductive oxide. The upper electrode UE may be formed of a conductive oxide such as ITO.

When the potential of the lower electrode LE is relatively higher than the potential of the upper electrode UE, the lower electrode LE corresponds to an anode, and the upper electrode UE corresponds to a cathode. In addition, when the potential of the upper electrode UE is relatively higher than the potential of the lower electrode LE, the upper electrode UE corresponds to an anode, and the lower electrode LE corresponds to a cathode.

The organic layer OR includes a pair of functional layers, and a light emitting layer arranged between these functional layers. As an example, the organic layer OR has a structure in which a hole-injection layer, a hole-transport layer, an electron blocking layer, a light emitting layer, a hole blocking layer, an electron-transport layer, and an electron-injection layer are stacked in this order.

The cap layer CP (CP1, CP2, and CP3) is formed of, for example, a multilayer body of a plurality of transparent thin films. As the plurality of thin films, the multilayer body may include a thin film formed of an inorganic material and a thin film formed of an organic material. In addition, these thin films have refractive indices different from each other. The materials of the thin films constituting the multilayer body are different from the materials of the upper electrode UE and are also different from the materials of the sealing layer SE. The cap layer CP may be omitted.

Common voltage is applied to the partition 6. This common voltage is supplied to each of the upper electrodes UE (first upper electrodes UE1a, UE2a, and UE3a) that are in contact with the side surfaces of the lower portion 61. A pixel voltage is supplied to the lower electrode LE (LE1, LE2, and LE3) through the pixel circuit 1 included in each sub-pixel SP (SP1, SP2, and SP3).

When a potential difference is formed between the lower electrode LE1 and the upper electrode UE1, the light emitting layer of the first organic layer OR1a emits light of the red wavelength range. When a potential difference is formed between the lower electrode LE2 and the upper electrode UE2, the light emitting layer of the first organic layer OR2a emits light of the green wavelength range. When a potential difference is formed between the lower electrode LE3 and the upper electrode UE3, the light emitting layer of the first organic layer OR3a emits light of the blue wavelength range.

As another example, the light emitting layers of the organic layers OR1, OR2, and OR3 may emit light of the same color (for example, white). In this case, the display device DSP may include a color filter that converts the light emitted from the light emitting layers into light of the color corresponding to the sub-pixels SP1, SP2, and SP3. In addition, the display device DSP may include a layer including quantum dots that are excited by the light emitted from the light emitting layers to generate the light of the colors corresponding to the sub-pixels SP1, SP2, and SP3.

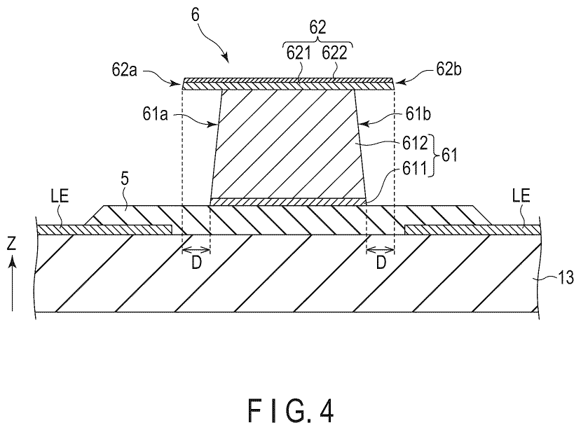

FIG. 4 is a schematic enlarged cross-sectional view of the partition 6. In FIG. 4, the elements other than the rib 5, the partition 6, the insulating layer 13 and a pair of lower electrodes LE are omitted. The pair of lower electrodes LE correspond to any of the above-described lower electrodes LE1, LE2 or LE3. In addition, the partition 6x and the partition 6y described above have the same structure as the partition 6 shown in FIG. 4.

In the example shown in FIG. 4, the lower portion 61 of the partition 6 includes a barrier layer (bottom portion) 611 arranged on the rib 5, and a metal layer (shaft portion) 612 arranged on the barrier layer 611. The barrier layer 611 is formed of a material different from the metal layer 612, for example, a metal material such as molybdenum (Mo), titanium (Ti), and titanium nitride (TiN). The metal layer 612 is formed so as to be thicker than the barrier layer 611. The metal layer 612 may include either a single-layer structure or a multilayer structure of different metal materials. As an example, the metal layer 612 is formed of, for example, aluminum (Al).

The upper portion (top portion) 62 is thinner than the lower portion 61. In the example shown in FIG. 4, the upper portion 62 includes a first layer 621 arranged on the metal layer 612, and a second layer 622 arranged on the first layer 621. As an example, the first layer 621 is formed of, for example, titanium (Ti) and the second layer 622 is formed of, for example, ITO.

In the example shown in FIG. 4, the width of the lower portion 61 becomes smaller toward the upper portion 62. In other words, side surfaces 61a and 61b of the lower portion 61 are inclined with respect to the third direction Z. The upper portion 62 includes an end portion 62a protruding from the side surface 61a and an end portion 62b protruding from the side surface 61b.

An amount D by which the end portions 62a and 62b protrude from the side surfaces 61a and 61b (hereinafter referred to as an amount of protrusion D of the partition 6) is, for example, 2.0 μm or less. The amount of protrusion D of the partition 6 in the embodiment corresponds to a length in the width direction (first direction X or second direction Y) orthogonal to the direction Z of the partition 6, between a lower end (barrier layer 611) of the side surfaces 61a and 61b, and the end portions 62a and 62b. In the example shown in FIG. 4, the side surfaces of the barrier layer 611 and the side surfaces of the metal layer 612 are aligned to form a plane having no steps. The side surfaces of the barrier layer 611 may slightly contract relative to the side surfaces of the metal layer 612 or may protrude relative to the side surfaces of the metal layer 612. In addition, in FIG. 4, the side surfaces of the barrier layer 611 and the metal layer 612 (in other words, the side surfaces 61a and 61b of the lower portion 61) are inclined with respect to the third direction Z. The side surfaces may be parallel to the third direction Z.

The structure of the partition 6 and the materials of each portion of the partition 6 can be selected as appropriate by considering, for example, a method of forming the partition 6, and the like.

In the present embodiment, the partition 6 is formed to divide the sub-pixels SP in plan view. The above-described organic layer OR is formed by, for example, anisotropic or directional vacuum evaporation. When the organic material for forming the organic layer OR is evaporated over the entire base 10 in a state in which the partition 6 is arranged, the organic layer OR is hardly formed on the side surfaces of the partition 6 since the partition 6 has the shape shown in FIG. 3 and FIG. 4. According to this, the organic layer OR (display element 20) which is divided for each sub-pixel SP by the partition 6 can be formed.

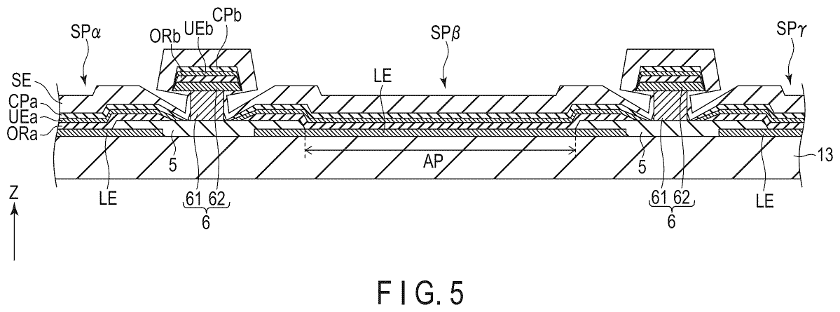

FIG. 5 to FIG. 7 are schematic cross-sectional views illustrating the display element 20 formed by using the partition 6. In FIG. 5 to FIG. 7, the base 10, the insulating layer 11, and the circuit layer 12 are omitted. Each of sub-pixels SPα, SPβ and SPγ shown in FIG. 5 to FIG. 7 corresponds to one of the sub-pixels SP1, SP2 and SP3.

In a state in which the partition 6 is arranged as described above, the organic layer OR, the upper electrode UE, the cap layer CP, and the sealing layer SE are formed in order on the entire base 10 by vapor deposition as shown in FIG. 5. The organic layer OR includes a light emitting layer which emits light exhibiting a color corresponding to sub-pixel SPα. The partition 6 having an overhang shape divides the organic layer OR into a first organic layer ORa which is in contact with the lower electrode LE through the aperture AP and a second organic layer ORb on the partition 6. The partition 6 divides the upper electrode UE into a first upper electrode UEa which covers the first organic layer ORa and the second upper electrode UEb which covers the second organic layer ORb. The partition 6 divides the cap layer CP into a first cap layer CPa which covers the first upper electrode UEa and a second cap layer CPb which covers the second upper electrode UEb. The first upper electrode UEa is in contact with the lower portion 61 of the partition 6. The sealing layer SE continuously covers the first cap layer CPa, the second cap layer CPb, and the partition 6.

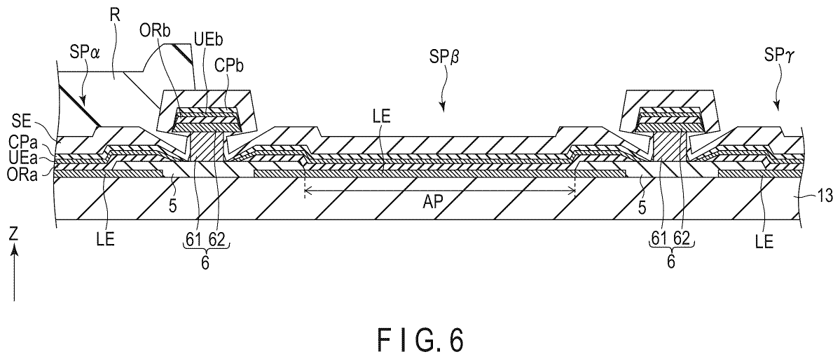

Next, a resist R is formed on the sealing layer SE as shown in FIG. 6. The resist R covers the sub-pixel SPα. In other words, the resist R is arranged directly above the first organic layer ORa, the first upper electrode UEa, and the first cap layer CPa, which are located in the sub-pixel SPα. The resist R is also located directly above portions close to the sub-pixel SPα, of the second organic layer ORb, the second upper electrode UEb, and the second cap layer CPb on the partition 6 between the sub-pixel SPα and the sub-pixel SPβ. In other words, at least a part of the partition 6 is exposed from the resist R.

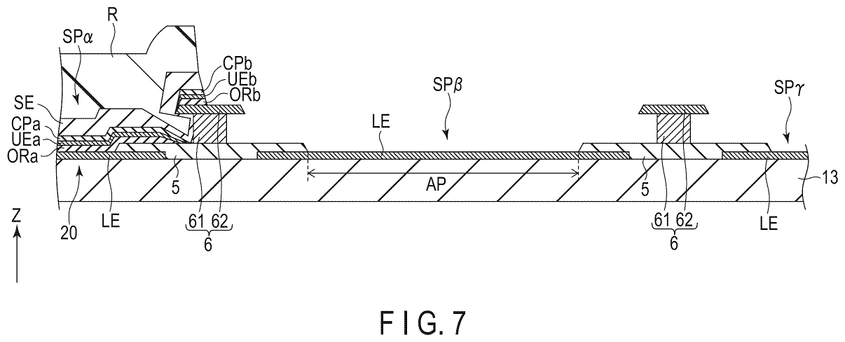

Furthermore, portions exposed from the resist R, of the organic layer OR, the upper electrode UE, the cap layer CP and the sealing layer SE, are removed as shown in FIG. 7, by etching using the resist R as a mask. The display element 20 including the lower electrode LE, the first organic layer ORa, the first upper electrode UEa, and the first cap layer CPa is thereby formed in the sub-pixel SPα. In contrast, the lower electrode LE is exposed in the sub-pixels SPβ and SPγ. The above-described etching includes, for example, dry etching of the sealing layer SE, wet etching and dry etching of the cap layer CP, wet etching of the upper electrode UE, and dry etching of the organic layer OR.

When the display element 20 of the sub-pixel SPα is formed as described above, the resist R is removed, and the display elements 20 of the sub-pixels SPβ and SPγ are formed in order similarly to the sub-pixel SPα.

The display elements 20 of the sub-pixels SP1, SP2, and SP3 are formed, and the resin layer 14, the sealing layer 15, and the resin layer 16 are formed, as exemplified for the above sub-pixels SPα, SPβ and SPγ, and the structure of the display device DSP shown in FIG. 3 is thereby implemented.

It is assumed that the display device DSP of the present embodiment is built in an electronic apparatus such as a smartphone and used together with, for example, a camera.

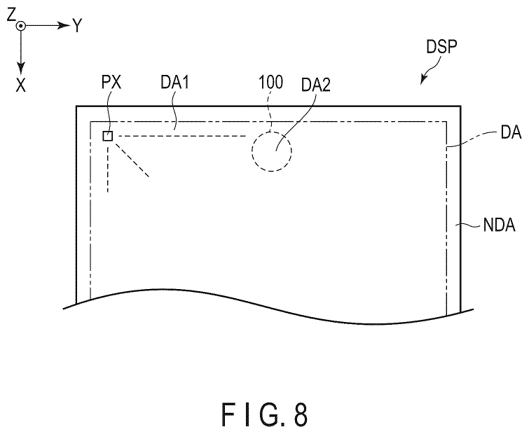

FIG. 8 is a plan view showing an electronic apparatus in which the display device DSP (display panel) of the present embodiment is incorporated. As described above, the display area DA in the display device DSP includes the plurality of pixels PX (sub-pixels SP1, SP2 and SP3) arranged in the matrix in the first direction X and the second direction Y. The display device DSP includes a display surface including the display area DA and a back surface opposed to the display surface (hereinafter referred to as the back surface of the display device DSP). In the electronic apparatus in which the display device DSP of the present embodiment is incorporated, a camera 100 for capturing images is arranged, for example, on the back surface side of the display device DSP.

In this case, as shown in FIG. 8, the camera 100 may be arranged on a portion overlapping with the display area DA (in other words, the plurality of pixels PX) in order to enlarge the display area DA in the electronic apparatus (display device DSP), in other words, to broaden the display area DA.

However, when the camera 100 is arranged on a position overlapping with the display area DA in plan view, the light transmissive of the portion overlapping with the camera 100 (in other words, the area including the pixel PX) may decrease due to the pixel circuit 1, the lower electrode LE, and the like included in each of the pixels PX overlapping with the camera 100. This may prevent sufficient light from entering in the camera 100 (imaging element thereof) through the display device DSP.

As a counter-measure, the some of the pixels PX may be removed from the area overlapping with the camera 100, for example. The configuration in which some of the pixels PX are simply removed decreases the resolution of the area overlapping with the camera 100 and makes the camera 100 easily recognizable from the area. This may decrease the display quality of the display device DSP.

Therefore, in the present embodiment, a configuration in which an area (size) of an aperture included in the rib 5 in plan view in an area overlapping with the camera 100 in the display area DA (hereinafter referred to as a second display area DA2) is smaller than an area (size) of an aperture included in the rib 5 in plan view in an area not overlapping with the camera 100 in the display area DA (hereinafter, referred to as a first display area DA1).

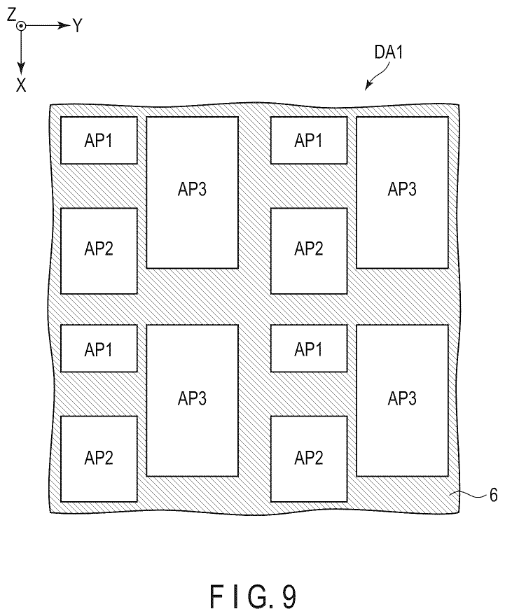

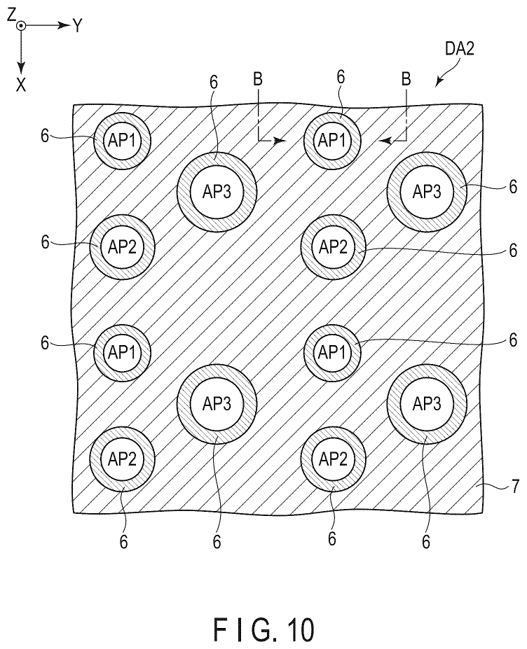

FIG. 9 is a view schematically showing an example of an arrangement of the apertures AP1, AP2, and AP3 included in the rib 5 formed in the first display area DA1. In contrast, FIG. 10 is a view schematically showing an example of an arrangement of the apertures AP1, AP2, and AP3 included in the rib 5 formed in the second display area DA2.

FIG. 9 and FIG. 10 show the apertures AP1, AP2, and AP3 included in the rib 5 in four pixels PX (sub-pixels SP1, SP2, and SP3). That is, in the present embodiment, the number of the apertures AP1, AP2, and AP3 per unit area in the first display area DA1 is the same as the number of the apertures AP1, AP2, and AP3 per unit area in the display area DA2.

Here, as shown in FIG. 9 and FIG. 10, the area of the aperture AP1 in the second display area DA2 is smaller than the area of the aperture AP1 in the first display area DA1. Similarly, the area of the aperture AP2 in the second display area DA2 is smaller than the area of the aperture AP2 in the first display area DA1. Further, the area of the aperture AP3 in the second display area DA2 is smaller than the area of the aperture AP3 in the first display area DA1.

In the examples shown in FIG. 9 and FIG. 10, the ratio of the areas of the apertures AP1, AP2, and AP3 in the first display area DA1 is significantly same as the ratio of the areas of the apertures AP1, AP2, and AP3 in the second display area DA2.

In the examples shown in FIG. 9 and FIG. 10, the apertures AP1, AP2, and AP3 in the first display area DA1 have rectangular shapes. In contrast, the apertures AP1, AP2, and AP3 in the second display area DA2 have circular shapes.

Further, as shown in FIG. 9, the plurality of apertures AP1, AP2, and AP3 in the first display area DA1 are divided by an integrally formed partition 6. In contrast, as shown in FIG. 10, each of the plurality of apertures AP1, AP2, and AP3 in the second display area DA2 is formed as an island-like pattern (in other words, formed in an island-like shape) and is divided by a plurality of partition 6 each individually surrounding each of the apertures AP1, AP2, and AP3.

The above FIG. 3 is the schematic cross-sectional view of the display device DSP in the first display area DA1. As described with reference to FIG. 3, the partitions 6 formed in the first display area DA1 are supplied with the common voltages. Thus, the upper electrode UE in contact with the side surfaces of the partition 6 (lower portion 61) (upper electrodes UE1, UE2, and UE3 overlapping with the apertures AP1, AP2, and AP3) can be supplied with the common electrodes via the partition 6.

In contrast, each of the plurality of partitions 6 formed in the second display area DA2 is formed as an independent island-like pattern (in other words, is arranged to have gaps between this partition 6 and other partitions 6). Therefore, a system to supply the plurality of partitions 6 with the common voltage is required.

In this case, in the present embodiment, a transparent conductive layer 7 is arranged so as to electrically connect the plurality of partitions 6 formed in the second display area DA2 with each other. This transparent conductive layer 7 can be formed of a transparent conductive oxide such as ITO and IZO. This configuration enables the plurality of partitions 6 formed in the second display area DA2 to be supplied with the common voltage and enables an area in which the transparent conductive layer 7 is arranged to achieve high transmittance.

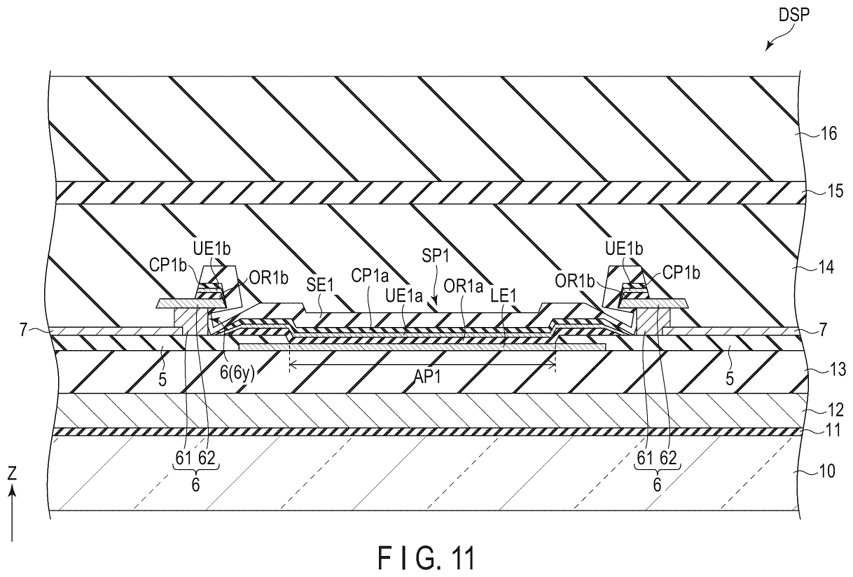

FIG. 11 is a schematic cross-sectional view showing the display device DSP along line B-B in FIG. 10. Portions shown in FIG. 11 equivalent to those shown in FIG. 3 are denoted by the same reference numbers, and detailed description thereof is omitted.

As shown in FIG. 11, in the second display area DA2, the partition 6 is arranged to divide the aperture AP1 and the display element 20 (lower electrode LE1, first organic layer OR1a, first upper electrode UE1a, and first cap layer CPla) is formed at a position overlapping with the aperture AP1.

This display element 20 is formed in a manner described with reference to FIG. 5 to FIG. 7. Thus, the second organic layer OR1b, the second upper electrode UE1b, and the second cap layer CP1b are arranged on the aperture AP1 side on the partition 6.

In contrast, in the second display area DA2 (area between the partition 6 dividing the aperture AP1 shown in FIG. 11 and a partition 6 dividing other apertures), which does not overlap with the aperture AP1 (in other words, the lower electrode LE1), the transparent conductive layer 7 (for example, ITO layer) is arranged on the rib 5.

In that case, a part of the transparent conductive layer 7 is covered with the partition 6 (lower portion 61) and the partition 6 (partition 6 dividing the aperture AP1) is electrically connected with the partition 6 dividing other apertures. In other words, each of the plurality of partitions 6 formed in the second display area DA2 is supplied with the common voltage via the transparent conductive layer 7.

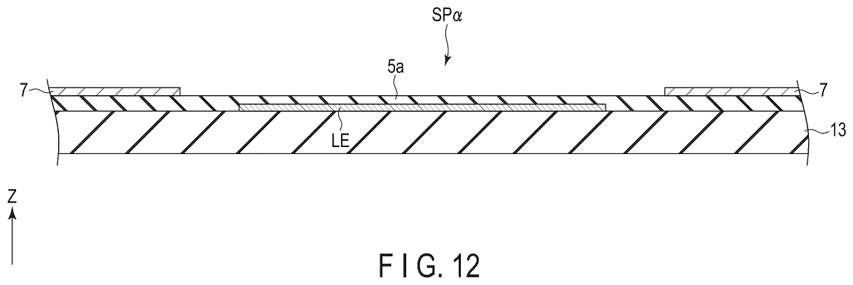

With reference to FIG. 12 to FIG. 14, an example of a process of forming the rib 5, the partition 6, and the transparent conductive layer 7 in the second display area DA2 will be described. In FIG. 12 to FIG. 14, the base 10, the insulating layer 11, and the circuit layer 12 are omitted. The sub-pixels SPα shown in FIG. 12 to FIG. 14 correspond to one of the sub-pixels SP1, SP2 and SP3.

First, as shown in FIG. 12, when the lower electrode LE is formed on the insulating layer 13, an insulating layer 5a formed of inorganic material, which is to be processed to the rib 5, is formed so as to cover the insulating layer 13 and the lower electrode LE, and the transparent conductive layer 7 is formed on the insulating layer 5a.

The insulating layer 5a is formed by the chemical vapor deposition. For example, after a transparent conductive layer (conductive oxide layer) is formed at least in the entire second display area DA2 by the sputtering method, the transparent conductive layer 7 is formed by removing a portion exposed from the resist (not shown) arranged on the transparent conductive layer by wet etching.

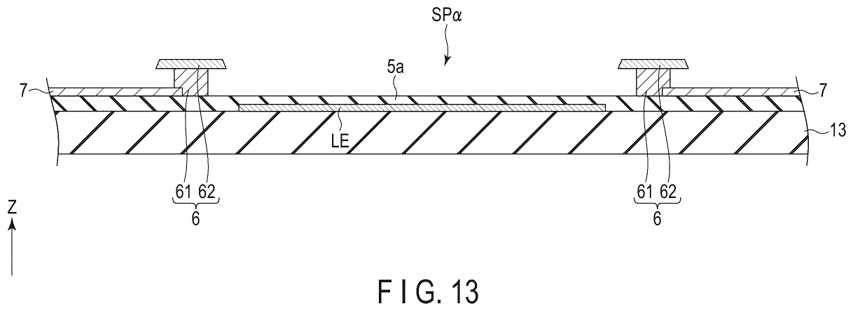

Next, as shown in FIG. 13, the partition 6 is formed such that a part of the transparent conductive layer 7 is covered with the lower portion 61. After a first layer to be processed to the lower portion 61 and a second layer to be processed to the upper portion 62 are formed by the sputtering method, the partition 6 is formed by removing a portion exposed from the resist (not shown) arranged on the second layer and the first layer by wet etching, dry etching, and the like.

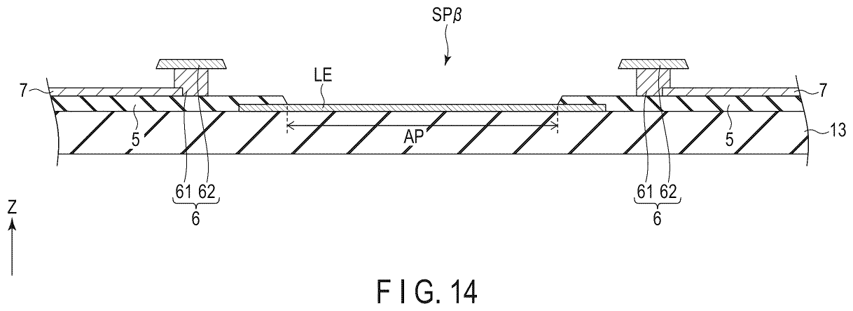

In addition, the resist patterned into the plan shape is arranged on the rib 5, and a portion of the insulating layer 5a that is exposed from the resist is removed by the dry etching. Thus, the rib 5 including apertures (AP1, AP2, and AP3) shown in FIG. 14 is formed.

Here, it is assumed that the rib 5, the partition 6, and the transparent conductive layer 7 are formed in the second display area DA2. The rib 5 and the partition 6 are formed in the first display area DA1 as well in the same process of forming the rib 5 and the partition 6 in the second display area DA2.

When the rib 5 and the partition 6 are formed in the first display area DAL and the rib 5, the partition 6, and the transparent conductive layer 7 are formed in the second display area DA2, the display element 20 is formed in each of the apertures AP1, AP2, and AP3 and further, the resin layer 14, the sealing layer 15, and the resin layer 16 are formed, as described with reference to FIG. 5 to FIG. 7. Thus, the configuration of the display device DSP of the present embodiment is achieved.

Here, it is assumed that the rib 5, the partition 6, and the transparent conductive layer 7 are formed in a manner described with reference to FIG. 12 to FIG. 14. The order of forming the rib 5, the partition 6, and the transparent conductive layer 7 can be changed as far as the configuration shown in FIG. 14 is achieved. More specifically, the transparent conductive layer 7 and the partition 6 may be formed after processing the insulating layer 5a, which is formed to cover the insulating layer 13 and the lower electrode LE, into the rib 5, for example. In other words, the apertures AP1, AP2, and AP3 may be formed prior to forming the transparent conductive layer 7 and the partition 6.

As described above, the display device DSP of the present embodiment includes the base 10, the lower electrode LE arranged on the base 10, the rib 5 including the aperture AP overlapping with the lower electrode, the partition 6 including the lower portion 61 arranged on the rib 5 and the upper portion 62 protruding from the side surfaces of the lower portion 61, the organic layer OR contacting the lower electrode LE through the aperture AP, the upper electrode UE arranged on the organic layer OR, and the sealing layer SE covering the upper electrode UE and the partition 6. In addition, in the present embodiment, the lower electrode LE includes the plurality of lower electrodes LE (first lower electrode) arranged in the first display area DA (first area) on the base 10 and the plurality of second lower electrodes LE (second lower electrode) arranged in the second display area DA2, which is different from the first display area DA1. The aperture AP includes the plurality of apertures AP (first apertures) overlapping with the plurality of lower electrodes LE arranged in the first display area DA1 and the plurality of apertures AP (second apertures) overlapping with the plurality of lower electrodes LE arranged in the second display area DA2.

In this case, in the present embodiment, the partition 6 includes the partition 6 (first partition) which divides the plurality of apertures AP in the first display area DA1 and the plurality of partitions 6 which divide each of the plurality of apertures AP in the second display area DA2. Each of the plurality of apertures AP in the second display area DA2 has an area smaller than that of each of the plurality of apertures AP in the first display area DA1. Further, each of the plurality of partitions 6 in the second display area DA2 are arranged to have gaps with other partitions 6 and are electrically connected to the other partitions 6 by the transparent conductive layer 7 arranged on the rib 5. As described above, similarly to the case of the first display area DA1, the organic layer OR is sealed by the lower electrode LE, the rib 5, the partition 6, and the sealing layer SE and each of the pixels is independently formed in the second display area DA2. Therefore, when one pixel becomes dark due to the moisture entering, moisture does not enter other pixels, suppressing the increase in the number of darken pixels. In the present embodiment, the second display area DA2 is arranged at a position overlapping with the camera 100 (imaging element) which light enters through the display device DSP, for example.

The configuration of the present embodiment can make light that enters the camera 100 transmitted through the transparent conductive layer 7 formed in the second display area DA2, and increase the light transmissivity in the second display area DA2. In addition, the present embodiment does not have to arrange the upper electrode UE, the sealing layer SE, and the like at positions overlapping with the transparent conductive layer 7, as shown in the above FIG. 11. Therefore, high light transmittance can be achieved in the area in which the transparent conductive layer 7 is arranged.

In addition, each of the plurality of partitions 6 in the second display area DA2 is arranged so as to cover a part of the transparent conductive layer 7. These plurality of partitions 6 are electrically connected to each other via the transparent conductive layer 7. Therefore, similarly to the case of the first display area DA1, the upper electrode UE can be supplied with the common voltage via each of the plurality of partitions 6 in the second display area DA2 as well.

In addition, in the present embodiment, the number of the apertures AP per unit area in the second display area DA2 can be the same as the number of the apertures AP per unit area in the first display area DA1 (in other words, the first display area DA1 and the second display area DA2 have the same resolution). Thus, the difference in the display quality between the first display area DA1 and the second display area DA2 can be reduced. In addition, reducing the difference in the display quality between the first display area DA1 and the second display area DA2 may lead to suppressing the boundary between the first display area DA1 and the second display area DA2 being visually recognizable or suppressing the camera 100 on a back side of the display device DSP being visually recognizable.

The areas of the apertures AP1, AP2, and AP3 in the second display area DA2 are smaller than the areas of the apertures AP1, AP2, and AP3 in the first display area DA1. Therefore, the luminance of the pixels PX (sub-pixels SP1, SP2 and SP3) arranged in the second display area DA2 is less than that of the pixel PX (sub-pixels SP1, SP2 and SP3) arranged in the first display area DA1. Thus, in the present embodiment, it is preferable that the difference in the luminance between the pixels PX arranged in the first display area DA1 and the pixels PX arranged in the second display area DA2 is reduced by adjusting the voltage supplied to the pixels PX (sub-pixels SP1, SP2 and SP3) arranged in the second display area DA2.

It is described that the ratio of the areas of the apertures AP1, AP2, and AP3 in the first display area DA1 is substantially same as the ratio of the areas of the apertures AP1, AP2, and AP3 in the second display area DA2. However, these ratios can be different from each other. More specifically, in the first display area DA1, it is described that the area of the aperture AP2 is greater than the area of the aperture AP1, and the area of the aperture AP3 is greater than the area of the aperture AP2. However, the areas of the apertures AP1, AP2, and AP3 in the second display area DA2 may be the same.

In addition, the areas (aperture ratio) of the apertures AP1, AP2, and AP3 in the second display area DA2 may be set based on the specification of the camera 100 (light amount and the like which the camera 100 requires) arranged on a back side of the display device DSP.

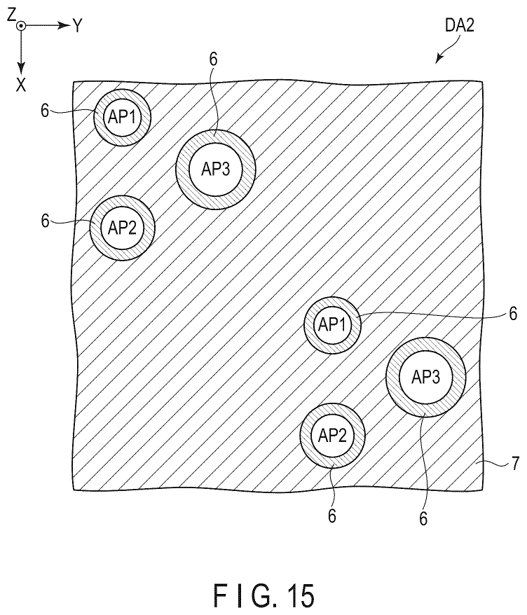

In addition, when higher transmittance is required according to the specification of the camera 100, the configuration shown in FIG. 15 in which some of the pixels PX arranged in the second display area DA2 are removed (in other words, reducing the number of the apertures AP per unit area in the second display area DA2 than the number of the apertures AP per unit area in the first display area DA1 for increasing the area of the transparent conductive layer 7 in the second display area DA2) may be adopted.

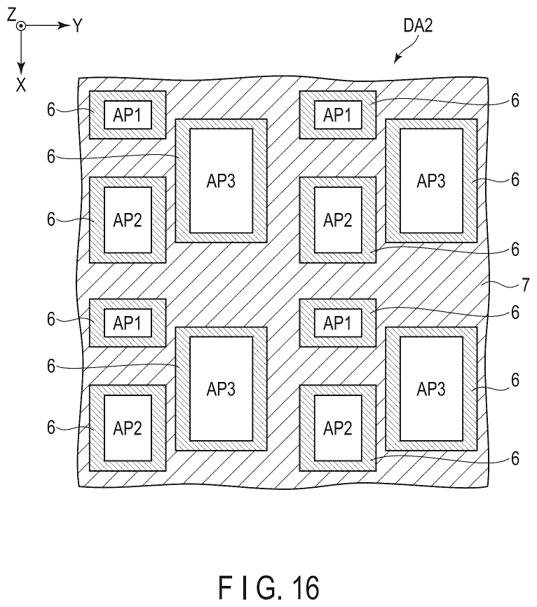

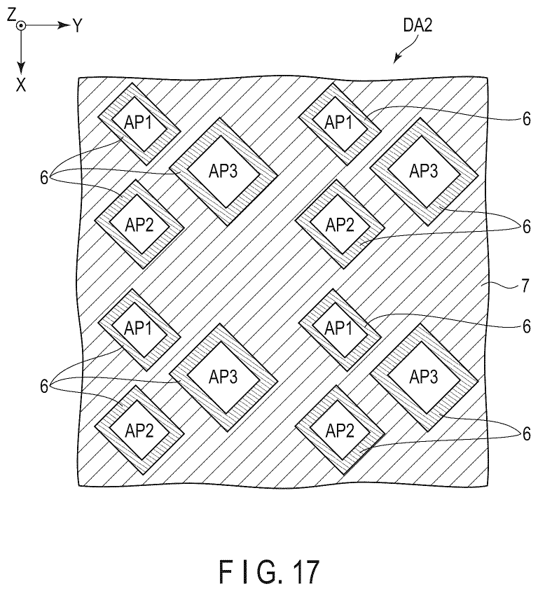

In addition, it is described that the areas of the apertures AP1, AP2, and AP3 in the second display area DA2 in the example shown in FIG. 10 each have the circular shape. The areas of the apertures AP1, AP2, and AP3 in the second display area DA2 may have other shapes as far as the areas of the apertures AP1, AP2, and AP3 in the second display area DA2 are smaller than the areas of the apertures AP1, AP2, and AP3 in the first display area DA1. More specifically, the apertures AP1, AP2, and AP3 in the second display area DA2 have rectangular shapes shown in FIG. 16 and FIG. 17. More specifically, the apertures AP1, AP2, and AP3 in the second display area DA2 have shapes different from each other. In addition, even when the apertures AP1, AP2, and AP3 have the rectangular shapes shown in FIG. 16 and FIG. 17 or other shapes, the configuration shown in FIG. 15 in which some of the pixels PX are removed can be adopted.

In the present embodiment, light passes through the transparent conductive layer 7 arranged between the plurality of partitions 6 and enters the camera 100. When the plurality of partitions 6 form a slit, light passes (is transmitted through) this slit is diffracted, and interference fringes may be formed in the camera 100 (imaging surface of the imaging element) located in lower side of the slit. In that case, compared to the case where the partition 6 is formed in a liner shape, when the partition 6 is formed in the curved shape, direction (angles) of diffraction of light passing through the slit formed by the partition 6 can be dispersed. Thus, the formation of the interference fringes affecting the image captured by the camera 100 on the imaging surface can be prevented. That is, the shapes of the apertures AP1, AP2, and AP3, and the partition 6 in the second display area DA2 are preferably configured so as not to affect images captured by the camera 100.

The present embodiment assumes that the camera 100 (imaging element thereof) is arranged on a back side of the display device DSP. The present embodiment can be adopted in a case where a sensor including photodetector and the like converting entering light to electric signals and devices including the sensor are arranged on a back side of the display device DSP. That is, the display device DSP of the present embodiment only has to include the configuration for increasing the light transmittance in a certain area in the display area DA. Portions arranged on a back side of the display device DSP are not limited.

In the present embodiment, it is described that each of the areas of the apertures AP in the second display area DA2 is smaller than each of the areas of the apertures AP in the first display area DA1. This signifies that each of the areas of the sub-pixels SP1, SP2 and SP3 in the second display area DA2 is smaller than each of the areas of the sub-pixels SP1, SP2 and SP3 in the first display area DA1.

All display devices and methods of manufacturing display devices, which are implementable with arbitrary changes in design by a person of ordinary skill in the art based on the display device and method of manufacturing display device described above as the embodiments of the present invention, belong to the scope of the present invention as long as they encompass the spirit of the present invention.

Various modifications are easily conceivable within the category of the idea of the present invention by a person of ordinary skill in the art, and these modifications are also considered to belong to the scope of the present invention. For example, additions, deletions or changes in design of the constituent elements or additions, omissions or changes in condition of the processes may be arbitrarily made to the above embodiments by a person of ordinary skill in the art, and these modifications also fall within the scope of the present invention as long as they encompass the spirit of the present invention.

In addition, the other advantages of the aspects described in the above embodiments, which are obvious from the descriptions of the specification or which are arbitrarily conceivable by a person of ordinary skill in the art, are considered to be achievable by the present invention as a matter of course.

What is claimed is:

1. A display device, comprising:
a base;
a lower electrode arranged on the base;
a rib including an aperture overlapping with the lower electrode;
a partition including a lower portion arranged on the rib and an upper portion protruding from side surfaces of the lower portion;
an organic layer in contact with the lower electrode through the aperture; and
an upper electrode arranged on the organic layer, wherein
the lower electrode includes a plurality of first lower electrodes arranged in a first area on the base and a plurality of second lower electrodes arranged in a second area different from the first area,
the aperture includes a plurality of first apertures overlapping with the plurality of first lower electrodes and a plurality of second apertures overlapping with the plurality of second lower electrodes,
the partition includes a first partition dividing the plurality of first apertures and a plurality of second partitions dividing each of the plurality of second apertures,
an area of each of the plurality of second apertures is smaller than an area of each of the plurality of first apertures, and
each of the plurality of second partitions is arranged to have gaps between the second partition and other second partition and is connected to the other second partitions via a transparent conductive layer arranged on the rib.

2. The display device of claim 1, wherein
the second area is arranged at a position overlapping with a photodetector receiving light via the display device.

3. The display device of claim 1, wherein
the number of the second apertures per unit area in the second area is the same as the number of the first apertures per unit area in the first area.

4. The display device of claim 1, wherein
the number of the second apertures per unit area in the second area is less than the number of the first apertures per unit area in the first area.

5. The display device of claim 1, wherein
the second aperture has a shape different from a shape of the first aperture.

6. The display device of claim 5, wherein
the first aperture has a rectangular shape, and
the second aperture has a circular shape.

7. The display device of claim 1, wherein
each of the plurality of second partitions is arranged to cover a part of the transparent conductive layer.

8. The display device of claim 1, further comprising:
a cap layer arranged on the upper electrode; and
a sealing layer arranged on the cap layer, wherein
the cap layer and the sealing layer are not arranged on the transparent conductive layer.

9. A display device, comprising:
a base;
a lower electrode arranged on the base;
a rib including an aperture overlapping with the lower electrode;
a partition including a lower portion arranged on the rib and an upper portion protruding from side surfaces of the lower portion;
an organic layer in contact with the lower electrode through the aperture; and
an upper electrode arranged on the organic layer, wherein
the lower electrode includes a plurality of first lower electrodes arranged in a first area on the base and a plurality of second lower electrodes arranged in a second area different from the first area,
the aperture includes a plurality of rectangular first apertures overlapping with the plurality of first lower electrodes and a plurality of second circular apertures overlapping with the plurality of second lower electrodes,
the partition includes a first partition dividing the plurality of first apertures and a plurality of second partitions dividing each of the plurality of second apertures,
each of the plurality of second partitions is arranged to have gaps between the second partition and other second partition and is connected to the other second partitions via a transparent conductive layer arranged on the rib, and
the second area is arranged at a position overlapping with a photodetector receiving light.

10. The display device of claim 9, wherein
the number of the second apertures per unit area in the second area is the same as the number of the first apertures per unit area in the first area.

11. The display device of claim 9, wherein
the number of the second apertures per unit area in the second area is less than the number of the first apertures per unit area in the first area.

12. The display device of claim 9, wherein
each of the plurality of second partitions is arranged to cover a part of the transparent conductive layer.

13. The display device of claim 9, further comprising:
a cap layer arranged on the upper electrode; and
a sealing layer arranged on the cap layer, wherein
the cap layer and the sealing layer are not arranged on the transparent conductive layer.

14. A method of manufacturing a display device, the method comprising:
forming a lower electrode on a base;
forming an insulating layer of an inorganic material, the insulating layer covering the lower electrode;
forming a transparent conductive layer on the insulating layer;
forming a partition including a lower portion arranged on the insulating layer and an upper portion protruding from side surfaces of the lower portion;
forming an aperture overlapping with the lower electrode on the insulating layer;
forming an organic layer in contact with the lower electrode through the aperture; and
forming an upper electrode on the organic layer, wherein
the lower electrode includes a plurality of first lower electrodes arranged in a first area on the base and a plurality of second lower electrodes arranged in a second area different from the first area,
the transparent conductive layer is formed in the second area, which does not overlap with the plurality of second lower electrodes,
the aperture includes a plurality of first apertures overlapping with the plurality of first lower electrodes and a plurality of second apertures overlapping with the plurality of second lower electrodes,
the partition includes a first partition dividing the plurality of first apertures and a plurality of second partitions dividing each of the plurality of second apertures,
an area of each of the plurality of second apertures is smaller than an area of each of the plurality of first apertures, and
each of the plurality of second partitions is arranged to have gaps between the second partition and other second partition and is connected to the other second partitions via the transparent conductive layer.

15. The method of claim 14, wherein
the second area is arranged at a position overlapping with a photodetector receiving light via the display device.

16. The method of claim 14, wherein
the number of the second apertures per unit area in the second area is the same as the number of the first apertures per unit area in the first area.

17. The method of claim 14, wherein
the number of the second apertures per unit area in the second area is less than the number of the first apertures per unit area in the first area.

18. The method of claim 14, wherein
the second aperture has a shape different from a shape of the first aperture.

19. The method of claim 18, wherein
the first aperture has a rectangular shape, and
the second aperture has a circular shape.

20. The method of claim 14, wherein
each of the plurality of second partitions is arranged to cover a part of the transparent conductive layer.
